(19) United States
(12) Patent Application Publication
(10) Pub. No.: US 2011/0299253 A1
(43) Pub. Date: Dec. 8, 2011

(54) ELECTRICAL POWER MODULE AND METHOD FOR CONNECTING AN ELECTRICAL POWER MODULE TO A PRINTED CIRCUIT BOARD AND A HEAT SINK

(75) Inventor: János Nabilek, Bicske (HU)

(73) Assignee: Vincotech Holdings S.a.r.l., Luxembourg (LU)

(21) Appl. No.: 13/106,194

(22) Filed: May 12, 2011

(30) Foreign Application Priority Data
Jun. 2, 2010 (DE) 10 2010 022 562.2

(51) Int. Cl. H05K 7/00; H05K 3/30

(52) U.S. Cl. 361/728; 29/837

(57) ABSTRACT

An electrical power module (2) to be mounted on a printed circuit board (1), comprising a first side (21) to be mounted on a surface of a heat sink (3), wherein, in a mounted position of the electrical power module (2) on the heat sink (3), the first side (21) is arranged substantially parallel to the heat sink (3), and a second side (22) provided with electrical connection elements (23), wherein the electrical connection elements (23) are adapted to electrically connect the electrical power module (2) to the printed circuit board (1). The electrical power module (2) is more easily connectable to the printed circuit board (1) and the heat sink (3) if the electrical power module (2) comprises at least one dowel-shaped fixing element (24) or is adapted to receive at least one dowel-shaped fixing element (24) which is introducible into at least one hole (31) of the heat sink (3) and is adapted to receive a clamping element (25) in such a way that the clamping element (25) is clamped in the at least one hole (31) of the heat sink (3) as result of introducing it into the at least one dowel-shaped fixing element (24).

### BACKGROUND OF THE INVENTION

The present invention relates to an electrical power module to be mounted on a printed circuit board, comprising a first side to be mounted on a surface of a heat sink, wherein, in a mounted position of the electrical power module on the heat sink, the first side is arranged substantially parallel to the heat sink, and a second side provided with electrical connection elements, wherein the electrical connection elements are adapted to electrically connect the electrical power module to the printed circuit board. The present invention also relates to a method for connecting an electrical power module to a printed circuit board and a heat sink.

An electrical power module is a module provided with semi-conductor devices, which is suited to dissipate the heat generated by the semi-conductor devices. In conventional electrical power modules the power module is usually connected to both the heat sink and the printed circuit board by means of screws. This involves a laborious and cost-intensive assembly of the power module and requires that enough space is available on the printed circuit board as several through-holes have to be provided on the printed circuit board for mounting the electrical power module.

Alternatively, a screw and clip fastener may be used to connect the power module to the printed circuit board. The printed circuit board is here connected to the power module by means of the clip elements of the housing of the power module, and the power module is connected to the heat sink by means of screws. Thus, the power module can be connected to the heat sink and the printed circuit board more easily. However, this fastening type requires that relatively large surfaces on the printed circuit board are recessed by milling which, again, leads to a loss of surface on the printed circuit board.

Another alternative to connect a power module to the printed circuit board and the heat sink is the connection of the power module and the printed circuit board by means of a screw. The power module and the printed circuit board are here connected to each other by means of a screw that is passed through a lid. This may facilitate mounting the power module on the printed circuit board, but the use of a lid is necessary and a large surface area is required for the printed circuit board because the lid is disposed on the printed circuit board. Moreover, through-holes on the printed circuit board are necessary, leading to an additional loss of space on the surface of the printed circuit board. Such an electrical power module is described in DE 196 30 173 C2.

### SUMMARY OF THE INVENTION

Therefore, it is the object of the present invention to provide an electrical power module to be mounted on a printed circuit board, which allows to connect the electrical power module to the printed circuit board and the heat sink in a simple manner and without the loss of surface area on the printed circuit board. Specifically, an electrical module is to be provided, which allows to connect the electrical power module to the printed circuit board and the heat sink in one single press-in method step without screws and additional process steps. Moreover, a corresponding method for connecting an electrical power module to a printed circuit board and a heat sink is to be provided.

This object is achieved with an electrical power module according to claim 1 and with a method for connecting an electrical power module to a printed circuit board and a heat sink according to claim 9. Additional embodiments are defined in the dependent patent claims.

Due to the fact that the electrical power module comprises at least one dowel-shaped fixing element or is adapted to receive at least one dowel-shaped fixing element which is introducible into at least one hole of the heat sink and is adapted to receive a clamping element in such a way that the clamping element is clamped in the at least one hole of the heat sink as result of introducing it into the at least one dowel-shaped fixing element, the electrical power module is connectable to the printed circuit board and the heat sink in an easy manner. Specifically, if the clamping element is introduced through a through-hole of the printed circuit board into the at least one dowel-shaped fixing element, the electrical power module is connectable to the printed circuit board and the heat sink in one single press-in method step.

Thus, an electrical power module can be pressed into the printed circuit board by means of press-in connection elements in one single step and can, at the same time, be fixed onto a heat sink. Contrary to the conventional mounting method for modules having press-in contacts, in which method the module is pressed into the circuit board and screwed onto the heat sink, the module pins are—according to the present invention—pressed into the printed circuit board, the module is fixed relative to the heat sink and the printed circuit board relative to the module in one single step.

In one embodiment of the electrical power module according to the invention the at least one dowel-shaped fixing element is integral with the electrical power module and is disposed on the first side of the electrical power module.

In an advantageous embodiment of the electrical power module according to the invention the at least one dowel-shaped fixing element comprises two semi-cylinders projecting from the first side of the electrical power module.

In another advantageous embodiment of the present invention the electrical power module comprises two dowel-shaped fixing elements each disposed at one end of the electrical power module and introducible into two corresponding holes of the heat sink.

In another embodiment of the present invention the electrical power module comprises at least one orifice to receive the at least one dowel-shaped fixing element.

In an advantageous embodiment of the present invention the electrical power module comprises two orifices to receive corresponding dowel-shaped fixing elements.

### BRIEF DESCRIPTION OF THE DRAWINGS

The invention shall be explained in more detail below by means of the embodiments illustrated in the accompanying drawings. Similar or corresponding details of the electrical power module according to the invention are provided with the same reference numbers throughout the figures, wherein:

FIG. 1 shows a perspective view of a system, comprising an inventive electrical power module, a heat sink, a printed circuit board and two clamping elements;

FIG. 2 shows a perspective view of a heat sink;

FIG. 3 shows a perspective lateral view of an inventive electrical power module;

FIG. 4 shows a lateral view of an inventive electrical power module connected to a heat sink and a printed circuit board by means of a clamping element;

FIG. 5 shows a perspective lateral view of the configuration shown in FIG. 4;

FIG. 6 shows a perspective view of the system shown in FIG. 1 in a pre-mounted state;

FIG. 7 shows an enlarged perspective view in a mounted state subsequent to the one of FIG. 6;

FIG. 8 shows a perspective view of the inventive electrical power module in a final mounted state;

FIG. 9 shows a perspective view of a system according to another embodiment of the present invention, comprising an electrical power module, a heat sink, a printed circuit board, dowel-shaped fixing elements and a clamping element;

FIG. 10 shows a perspective sectional view of the system shown in FIG. 9 in a final mounted state;

FIG. 11 shows a perspective view of an electrical power module according to another embodiment of the present invention;

FIG. 12 shows the backside of the electrical power module shown in FIG. 11;

FIG. 13 shows a perspective view of a system according to the further embodiment of the present invention, comprising an electrical power module like the one of FIG. 11 and FIG. 12, a heat sink and a printed circuit board;

FIG. 14 shows a perspective view of the system shown in FIG. 13 in another mounted state;

FIG. 15 shows a perspective view of the system shown in FIG. 14 in a final mounted state; and

FIG. 16 shows a perspective sectional view of the system shown in FIG. 15 in final mounted state.

### DETAILED DESCRIPTION

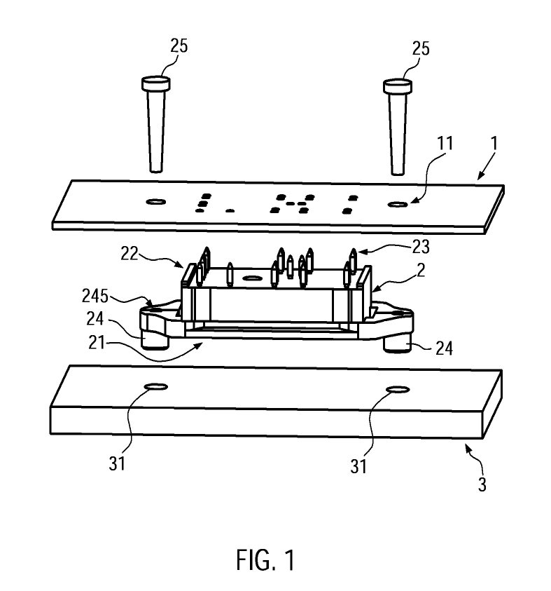

A system comprising an electrical power module 2 according to the present invention, a printed circuit board 1 and a heat sink 3 interconnected by means of clamping elements 25 is shown in a perspective view in FIG. 1.

The electrical power module 2 according to the invention to be mounted on a printed circuit board 1 comprises a first side 21 to be mounted on a surface of a heat sink 3 and a second side 22, which is provided with electrical connection elements 23, to be mounted on the printed circuit board 1. The first side 21 of the electrical power module 2 is adapted to be mounted on a surface of the heat sink 3. To this end, the first side 21 comprises two dowel-shaped fixing elements 24, 24′ each disposed at one end of the electrical power module 2 and introducible into two corresponding holes 31, 31′ of the heat sink 3.

In a mounted position of the electrical power module 2 according to the invention on the heat sink 3 the first side 21 of the electrical power module 2 is disposed substantially parallel relative to the heat sink 3. The electrical connection elements 23 of the second side 22 of the electrical power module 2 are substantially perpendicular relative to the second side 22 of the electrical power module 2 and serve to electrically connect the electrical power module 2 to the printed circuit board 1.

As shown in FIG. 1, the electrical power module according to the invention further comprises two clamping elements 25, 25′. Preferably, the clamping elements 25, 25′ are made of plastic and are substantially oblong pins penetrating through corresponding through-holes 11 of the printed circuit board 1 and into corresponding holes 245 of the dowel-shaped fixing elements 24, 24′. The clamping elements may have different shapes, e.g. a plain shape consisting of a stud and a head, or a conical shape or a shape including a shoulder. The function thereof shall by explained in more detail below by means of the other drawings.

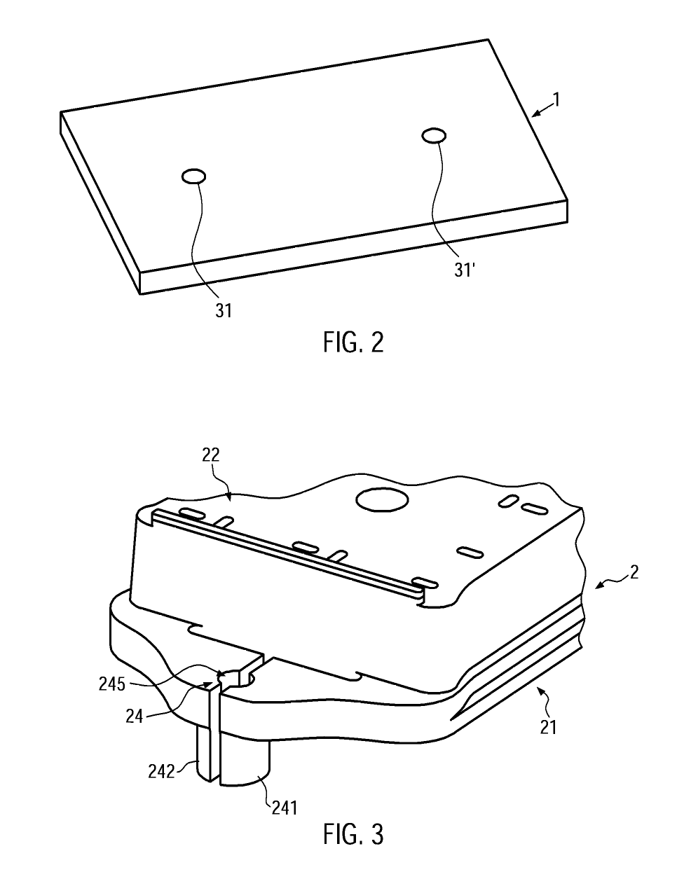

FIG. 2 shows a perspective view of a heat sink 3 comprising holes 31, 31′. The heat sink 3 substantially is a thermally conductive plate onto which the electrical power module 2 can be mounted, with the number of holes 31, 31′ being chosen in correspondence with the number of the dowel-shaped fixing elements 24, 24′ on the first side 21 of the electrical power module 2.

FIG. 3 shows a perspective lateral view of the electrical power module 2. As can be seen in this figure the electrical power module 2 comprises a dowel-shaped fixing element 24 made of two semi-cylinders 241, 242 which project from the first side 21 of the electrical power module 2.

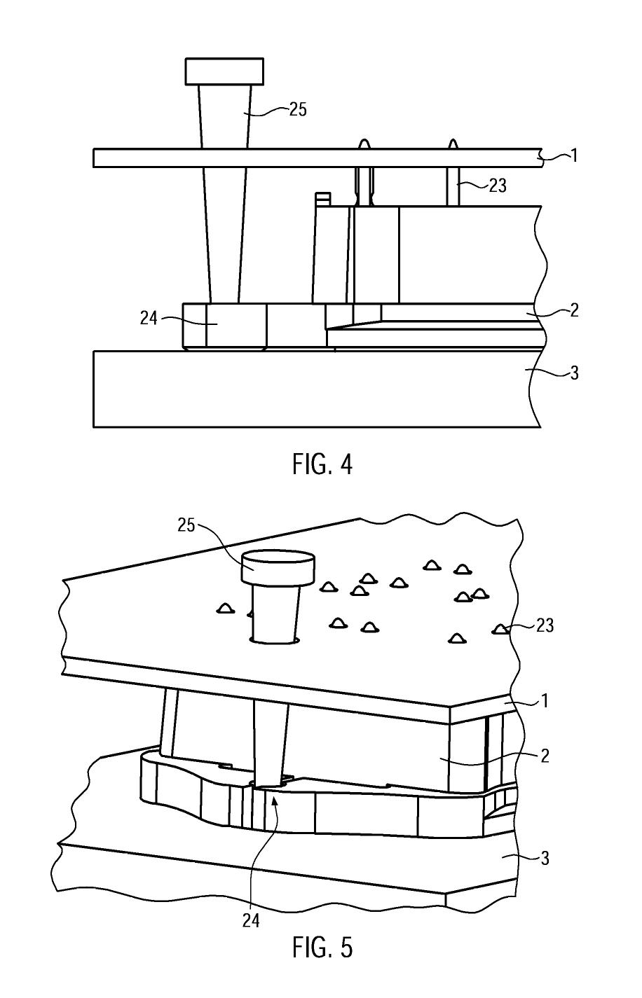

FIG. 4 shows an enlarged lateral view of the electrical power module 2 in a mounted position on the surface of the heat sink 3, wherein the electrical power module 2 is not yet in a final mounted position. A clamping element 25 is shown, which is introduced through a through-hole (not shown) of the printed circuit board 1 and into the orifice 245 of the dowel-shaped fixing element 24 shown in FIG. 3. The electrical connection elements 23 of the electrical power module 2 are disposed in corresponding through-holes of the printed circuit board 1, with the electrical connection elements 23 not yet being in their final mounted position.

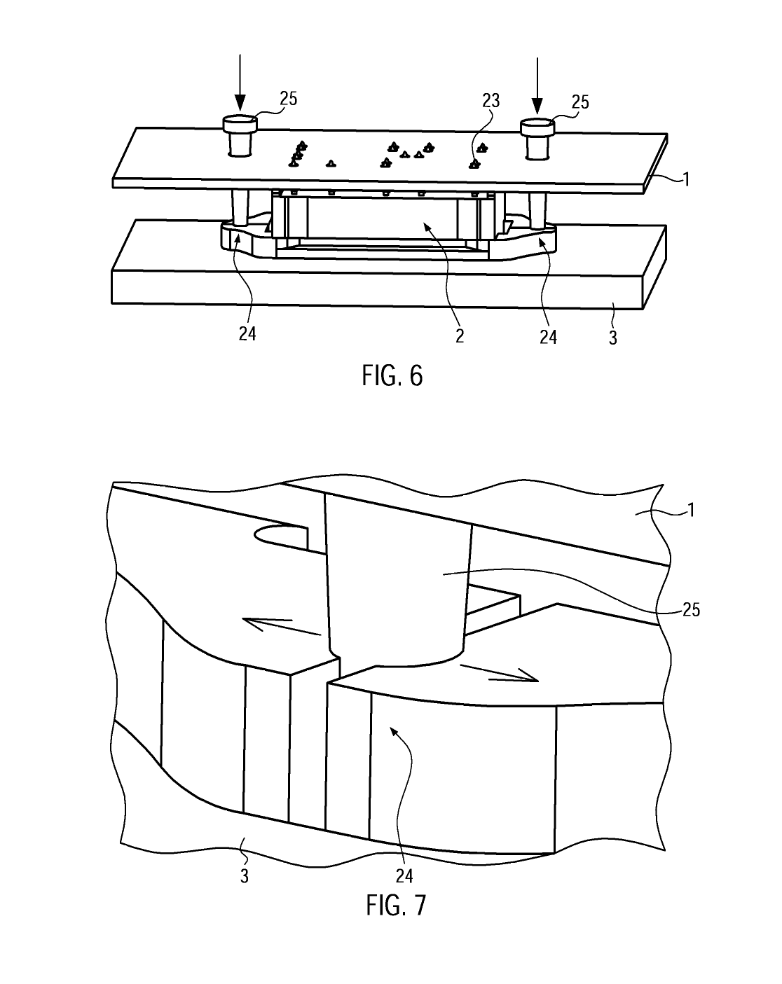

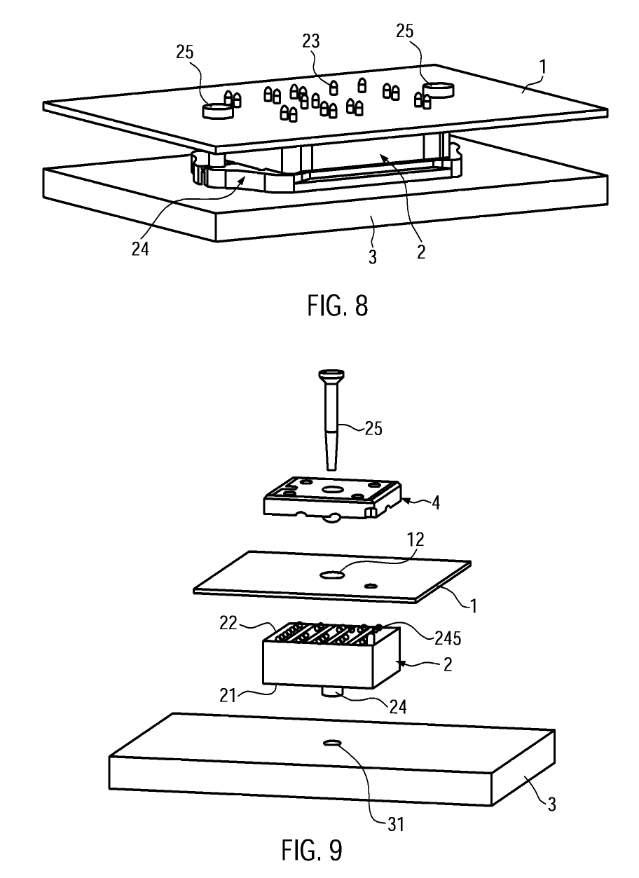

FIG. 5 shows a perspective lateral view of the electrical power module 2 in the configuration shown in FIG. 4. FIG. 6 shows that the method for connecting the electrical power module 2 to the printed circuit board 1 and the heat sink 3 requires that the clamping elements 25, 25′ are introduced into the dowel-shaped fixing elements 24, 24′, preferably by pressing onto the clamping elements 25, 25′. FIG. 7 shows how pressing the clamping elements 25, 25′ along the vertical direction exerts a pressure on the upper portions of the two semi-cylinders 241, 242. Thus, resulting from the introduction of the clamping element 25 into the dowel-shaped fixing element 24, the clamping element 25 is clamped in the hole of the heat sink 3, thereby achieving a final mounted state of the electrical power module 2, which is shown in FIG. 8.

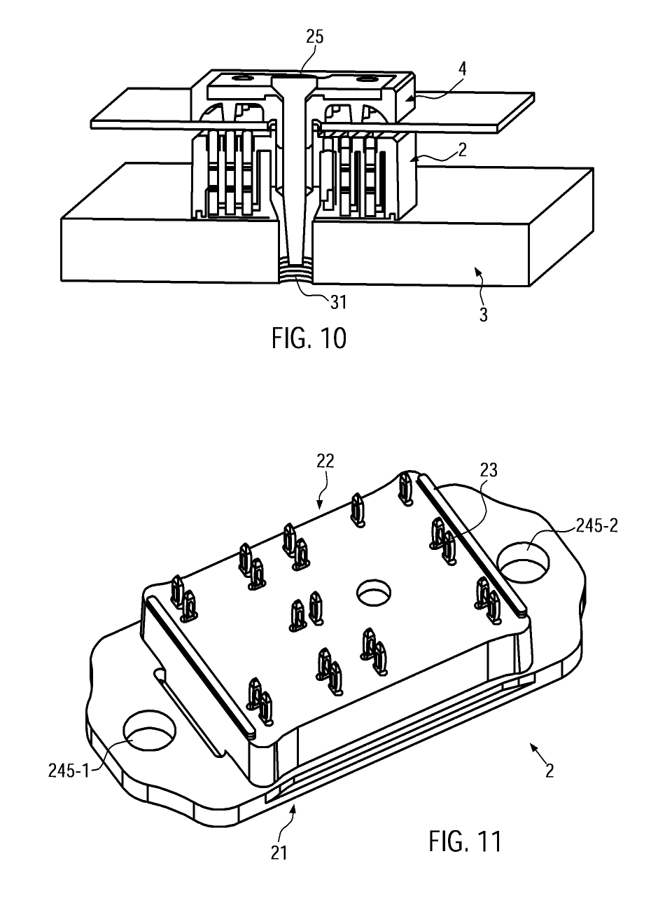

FIG. 9 shows another embodiment of a system, comprising an electrical power module 2 according to the present invention, a printed circuit board 1 and a heat sink 3. As can be seen in FIG. 9, the electrical power module 2 comprises a single dowel-shaped fixing element 24. This single dowel-shaped fixing element 24 is located substantially in the center of the first side 21 of the electrical power module 2. The dowel-shaped fixing element 24 projects from the first side 21 of the electrical power module 2 and can be introduced into a corresponding hole 31 of the heat sink 3. A corresponding orifice 245 is provided on the second side 22 of the electrical power module 2, which corresponds to a through-hole 12 in the printed circuit board 1, into which the clamping element 25 is introduced through a lid 4 disposed between the printed circuit board 1 and the clamping element 25. By introducing the clamping element 25, the electrical power module 2 is brought into a final mounted state according to the principles described above. FIG. 10 shows a perspective sectional view of the final mounted state of the electrical power module 2.

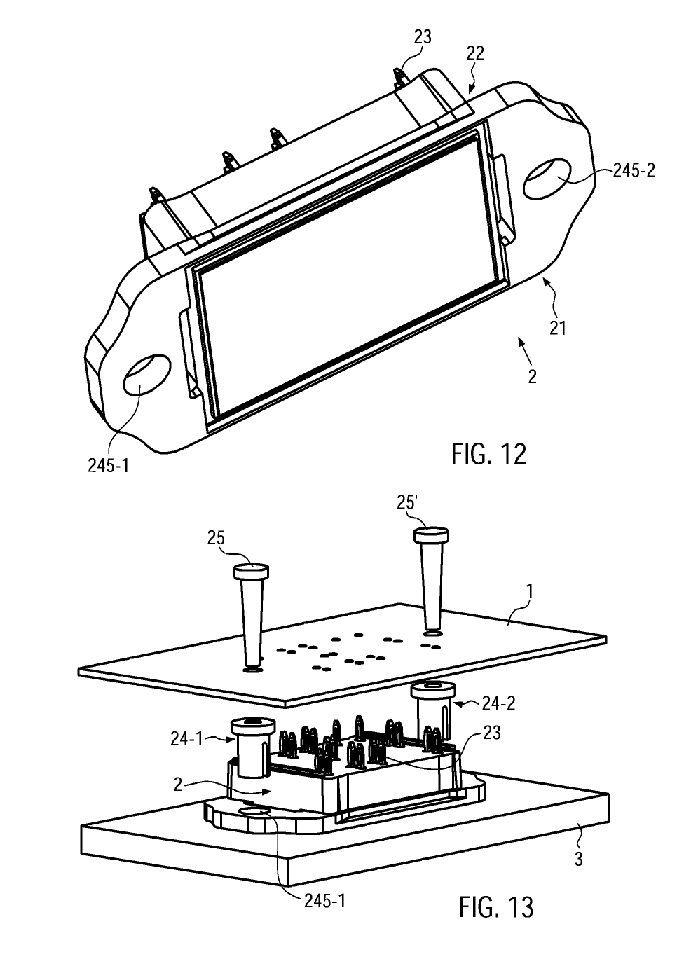

FIG. 11 shows another embodiment of an electrical power module 2 according to the present invention, wherein the dowel-shaped fixing element is not integral with the electrical power module 2. The electrical power module 2 shown in FIG. 11 comprises two orifices 245-1, 245-2 which are adapted to receive corresponding fixing elements (not shown). FIG. 12 shows the other side of the electrical power module 2 shown in FIG. 11.

FIG. 13 shows a perspective view of a system according to another embodiment of the present invention, comprising a printed circuit board 1 and a heat sink 3, using the electrical power module 2 according to the embodiment as shown in FIG. 11 and FIG. 12. In this embodiment dowel-shaped fixing elements 24-1, 24-2 are introduced into the corresponding orifices 245-1, 245-2 (not shown) of the electrical power module 2 and into the corresponding holes (not shown) of the heat sink 3. As described above already with respect to the first embodiment, the clamping elements 25, 25′ are introduced into the corresponding orifices of the printed circuit board 1 and into the fixing elements 24-1, 24-2, entailing that both the heat sink 3 and the printed circuit board 1 are connected to the electrical power module 2 at the same time in one single step.

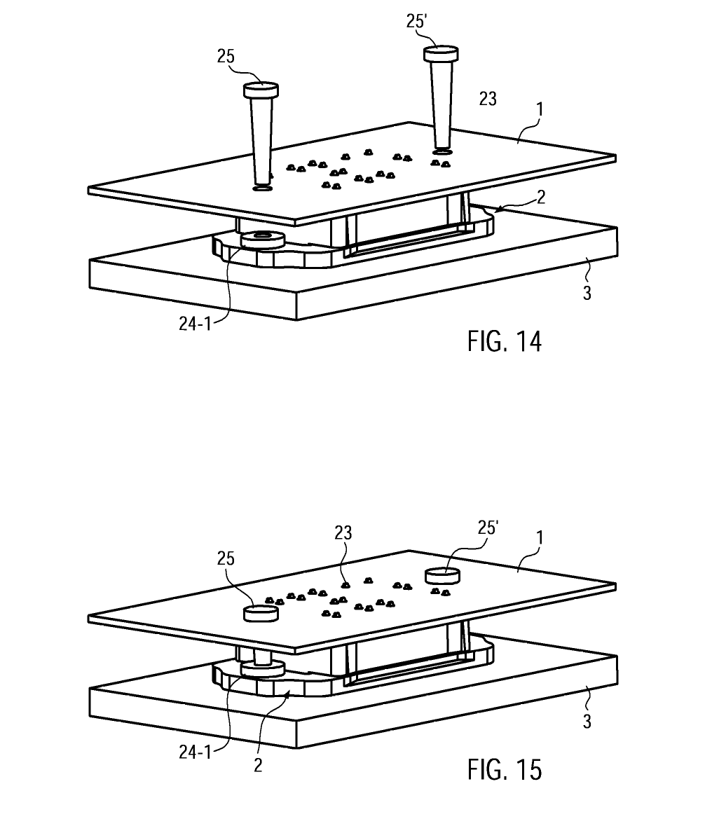

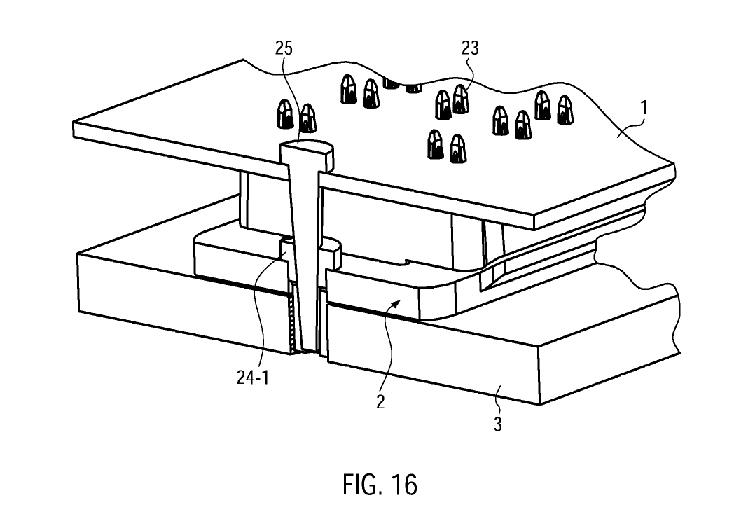

FIG. 14 shows the mounted state prior to the introduction of the clamping elements 25, 25′ into the corresponding orifices of the printed circuit board 1. FIG. 15 shows the final mounted state of the system. FIG. 16 shows a perspective sectional view of the system shown in FIG. 15 in a final mounted state.

1. An electrical power module (2) to be mounted on a printed circuit board (1), comprising:
a first side (21) to be mounted on a surface of a heat sink (3), wherein, in a mounted position of the electrical power module (2) on the heat sink (3), the first side (21) is arranged substantially parallel to the heat sink (3), and
a second side (22) provided with electrical connection elements (23), wherein the electrical connection elements (23) are adapted to electrically connect the electrical power module (2) to the printed circuit board (1),
wherein the electrical power module (2) comprises at least one dowel-shaped fixing element (24) or is adapted to receive at least one dowel-shaped fixing element (24) which is introducible into at least one hole (31) of the heat sink (3) and is adapted to receive a clamping element (25) in such a way that the clamping element (25) is clamped in the at least one hole (31) of the heat sink (3) as result of introducing it into the at least one dowel-shaped fixing element (24).

2. An electrical power module according to claim 1, wherein the at least one dowel-shaped fixing element (24) is integral with the electrical power module (2) and is disposed on the first side (21) of the electrical power module (2).

3. An electrical power module according to claim 1, wherein the at least one dowel-shaped fixing element (24) comprises two semi-cylinders (241, 242) projecting from the first side (21) of the electrical power module (2).

4. An electrical power module according to claim 1, wherein the electrical power module (2) comprises two dowel-shaped fixing elements (24, 24′) each disposed at one end of the electrical power module (2) and introducible into two corresponding holes (31, 31′) of the heat sink (3).

5. An electrical power module according to claim 1, wherein the electrical power module (2) comprises at least one orifice (245-1) to receive the at least one dowel-shaped fixing element (24-1).

6. An electrical power module according to claim 5, wherein the electrical power module (2) comprises two orifices (245-1, 245-2) to receive two corresponding dowel-shaped fixing elements (24-1, 24-2).

7. A system comprising an electrical power module according to claim 1, wherein the at least one hole (31) of the heat sink (3) is one from a plain hole, a conical hole or a threaded hole and the at least one dowel-shaped fixing element (24) has a corresponding plain, conical or threaded outer shape.

8. A system according to claim 7, further comprising a lid (4) disposed between the printed circuit board (1) and the clamping element (25).

9. A method for connecting an electrical power module (2) to a printed circuit board (1) and a heat sink (3), the method comprising the following steps:
mounting a first side (21) of the electrical power module (2) on a surface of a heat sink (3), wherein, in the mounted position of the electrical power module (2) on the heat sink (3), the first side (21) is arranged substantially parallel to the heat sink (3),
connecting a second side (22) of the electrical power module (2) provided with electrical connection elements (23) to the printed circuit board (1) by introducing the electrical connection elements (23) into corresponding through-holes (11) of the printed circuit board (1), and
introducing at least one dowel-shaped fixing element (24) of the electrical power module (2) into at least one hole (31) of the heat sink (3),
wherein the electrical power module (2) is brought into a final mounted state by introducing a clamping element (25) through a through-hole (12) of the printed circuit board (1) into the at least one dowel-shaped fixing element (24) in such a way that, resulting from the introduction of the clamping element (25) into the at least one dowel-shaped fixing element (24), the clamping element (25) is clamped in the at least one hole (31) of the heat sink (3).
